(19) United States
(12) Patent Application Publication
(10) Pub. No.: US 2023/0096304 A1
(43) Pub. Date: Mar. 30, 2023

(54) Display Substrate, Preparation Method Thereof, and Display Device

(71) Applicants: Chengdu BOE Optoelectronics Technology Co., Ltd., Chengdu, Sichuan (CN); BOE Technology Group Co., Ltd., Beijing (CN)

(72) Inventor: De YUAN, Beijing (CN)

(21) Appl. No.: 17/608,984

(22) PCT Filed: Jan. 26, 2021
(86) PCT No.: PCT/CN2021/073840

§ 371 Date: Nov. 4, 2021

(51) Int. Cl. H01L 27/32; H01L 51/52

(52) U.S. Cl. CPC H01L 27/3246; H01L 51/5275; H01L 51/5284

(57) ABSTRACT

The display substrate includes a driving structure layer disposed on a base substrate, a light emitting structure layer disposed on the side of the driving structure layer away from the base substrate, and a modulation structure layer disposed on the side of the light emitting structure layer away from the base substrate; the modulation structure layer includes a light extraction layer and a light block layer, the light extraction layer is disposed on the side of a cathode in the light emitting structure layer away from the base substrate, the light block layer is disposed on the side of the light extraction layer away from the base substrate, the refractive index of the light extraction layer is greater than the refractive indexes of the cathode and the light block layer, and the light block layer is configured to block ultraviolet rays from being incident on a pixel definition layer.

### CROSS-REFERENCE TO RELATED APPLICATION

The present application is a U.S. National Phase Entry of International Application No. PCT/CN2021/073840 having an international filing date of Jan. 26, 2021, the entire content of which is hereby incorporated by reference.

### TECHNICAL FIELD

The present disclosure relates to, but is not limited to, the field of display technology, in particular to a display substrate, a preparation method thereof and a display device.

### BACKGROUND

As a new type of flat panel display device, Organic Light Emitting Devices (OLEDs) have attracted more and more attention. An OLED is an active light emitting device, which has the advantages of high brightness, color saturation, ultra-thinness, wide angle of view, low power consumption, extremely high response speed, and flexibility, can well satisfy the personalized needs of users. With the continuous development of display technology, display devices using OLEDs as light emitting elements and using Thin Film Transistors (TFTs) for signal control have become the mainstream products in the display field.

### SUMMARY

The following is a brief description of the subject matter described in detail in the present disclosure. This brief description is not intended to limit the scope of protection of the claims.

A display substrate includes a driving structure layer disposed on a base substrate, a light emitting structure layer disposed on the side of the driving structure layer away from the base substrate, and a modulation structure layer disposed on the side of the light emitting structure layer away from the base substrate, wherein the modulation structure layer includes a light extraction layer and a light block layer, the light extraction layer is disposed on the side of a cathode in the light emitting structure layer away from the base substrate, the light block layer is disposed on the side of the light extraction layer away from the base substrate, the refractive index of the light extraction layer is greater than the refractive indexes of the cathode and the light block layer, and the light block layer is configured to block ultraviolet rays from being incident on a pixel definition layer.

In an exemplary embodiment, the display substrate further includes an encapsulation structure layer disposed on the side of the modulation structure layer away from the base substrate, the encapsulation structure layer includes a first encapsulation layer disposed on the side of the modulation structure layer away from the base substrate, a second encapsulation layer disposed on the side of the first encapsulation layer away from the base substrate, and a third encapsulation layer disposed on the side of the second encapsulation layer away from the base substrate; the refractive index of the light block layer is less than the refractive index of the first encapsulation layer.

In an exemplary embodiment, the modulation structure layer further includes a protective layer, the protective layer is disposed between the light extraction layer and the light block layer, the refractive index of the light extraction layer is greater than the refractive indexes of the cathode and the protective layer, and the refractive index of the light block layer is greater than the refractive indexes of the protective layer and the first encapsulation layer in the encapsulation structure layer.

In an exemplary embodiment, the material of the light extraction layer includes an aromatic amine organic matter and the material of the protective layer includes lithium fluoride.

In an exemplary embodiment, the thickness of the light extraction layer is 60 nm to 100 nm, the thickness of the protective layer is 60 nm to 100 nm, and the thickness of the light block layer is greater than 50 nm.

In an exemplary embodiment, the refractive index of the light extraction layer is 1.7 to 2.0, the refractive index of the protective layer is 1.4 to 1.6, and the refractive index of the light block layer is 1.6 to 2.1.

In an exemplary embodiment, the light emitting structure layer includes an anode and a pixel definition layer; a pixel opening exposing the anode is disposed in the pixel definition layer, a light outlet is disposed in the light block layer, and an orthographic projection of the light outlet on the base substrate contains an orthographic projection of the pixel opening on the base substrate.

In an exemplary embodiment, the light block layer includes any one or more of an ultraviolet absorption layer and an ultraviolet reflection layer.

In an exemplary embodiment, the ultraviolet absorption layer includes an aromatic amine organic matter added with an N heteroatom or an O heteroatom.

In an exemplary embodiment, the ultraviolet reflection layer includes a plurality of sub-layers stacked sequentially, the plurality of sub-layers include a first sub-layer with a first refractive index and a second sub-layer with a second refractive index, and the first sub-layer and the second sub-layer are arranged alternately in the plurality of sub-layers.

A display device includes the display substrate described above.

A method for preparing a display substrate includes: sequentially forming a driving structure layer and a light emitting structure layer on a base substrate; and forming a modulation structure layer on the light emitting structure layer, wherein the modulation structure layer includes a light extraction layer and a light block layer, the light extraction layer is disposed on the side of a cathode in the light emitting structure layer away from the base substrate, the light block layer is disposed on the side of the light extraction layer away from the base substrate, the refractive index of the light extraction layer is greater than the refractive indexes of the cathode and the light block layer, and the light block layer is configured to block ultraviolet rays from being incident on a pixel definition layer.

In an exemplary embodiment, the method further includes: forming an encapsulation structure layer on the modulation structure layer, wherein the encapsulation structure layer includes a first encapsulation layer disposed on the side of the modulation structure layer away from the base substrate, a second encapsulation layer disposed on the side of the first encapsulation layer away from the base substrate, and a third encapsulation layer disposed on the side of the second encapsulation layer away from the base substrate; the refractive index of the light block layer is less than the refractive index of the first encapsulation layer.

In an exemplary embodiment, the modulation structure layer further includes a protective layer, the protective layer is disposed between the light extraction layer and the light block layer, the refractive index of the light extraction layer is greater than the refractive indexes of the cathode and the protective layer, and the refractive index of the light block layer is greater than the refractive indexes of the protective layer and the first encapsulation layer in the encapsulation structure layer.

In an exemplary embodiment, the light emitting structure layer includes an anode and a pixel definition layer; a pixel opening exposing the anode is disposed in the pixel definition layer, a light outlet is disposed in the light block layer, and an orthographic projection of the light outlet on the base substrate contains an orthographic projection of the pixel opening on the base substrate.

After reading and understanding the drawings and the detailed description, other aspects may be understood.

### BRIEF DESCRIPTION OF DRAWINGS

The drawings are used to provide a further understanding of the technical solution of the present disclosure, constitute a part of the description, are used together with the embodiments of the present disclosure to explain the technical solution of the present disclosure, and do not constitute limitations to the technical solution of the present disclosure. The shape and size of at least one component in the drawings do not reflect the actual scale, and the purpose is only to schematically illustrate the contents of the present disclosure.

FIG. 1 illustrates a schematic diagram of a structure of an OLED display device.

FIG. 2 illustrates a schematic diagram of a planar structure of a display substrate.

FIG. 3 illustrates an equivalent circuit diagram of a pixel driving circuit.

FIG. 4 illustrates a schematic diagram of a sectional structure of a display substrate according to an exemplary embodiment of the present disclosure.

FIG. 5 illustrates a schematic diagram after a driving structure layer pattern is formed according to an exemplary embodiment of the present disclosure.

FIG. 6 illustrates a schematic diagram after a light emitting structure layer pattern is formed according to an exemplary embodiment of the present disclosure.

FIG. 7 illustrates a schematic diagram after a modulation structure layer pattern is formed according to an exemplary embodiment of the present disclosure.

FIG. 8 illustrates a schematic diagram after an encapsulation structure layer pattern is formed according to an exemplary embodiment of the present disclosure.

FIG. 9 illustrates a schematic diagram of service life simulation results of a display substrate according to an exemplary embodiment of the present disclosure.

FIG. 10 illustrates a schematic diagram of a sectional structure of another display substrate according to an exemplary embodiment of the present disclosure.

FIG. 11 illustrates a schematic diagram of light extraction efficiency simulation results of a display substrate according to an exemplary embodiment of the present disclosure.

FIG. 12 illustrates a schematic diagram of a sectional structure of another display substrate according to an exemplary embodiment of the present disclosure.

FIG. 13 illustrates a schematic diagram of a sectional structure of another display substrate according to an exemplary embodiment of the present disclosure.

FIG. 14 illustrates a schematic diagram after another modulation structure layer pattern is formed according to an exemplary embodiment of the present disclosure.

FIG. 15 illustrates a schematic diagram of a sectional structure of another display substrate according to an exemplary embodiment of the present disclosure.

FIG. 16 illustrates a schematic diagram of a sectional structure of another display substrate according to an exemplary embodiment of the present disclosure.

FIG. 17 illustrates a schematic diagram after another modulation structure layer pattern is formed according to an exemplary embodiment of the present disclosure.

FIG. 18 illustrates absorption curves of NCPL and HCPL at different bands.

Explanation of reference signs:

1-glass carrier plate;
10-base substrate;
11-first insulating layer;
12-second insulating layer;
13-third insulating layer;
14-fourth insulating layer;
15-fifth insulating layer;
21-anode;
22-pixel definition layer;
23-organic light emitting layer;
24-cathode;
31-light extraction layer;
32-protective layer;
33-light block layer;
34-light outlet;
41-first encapsulation layer;
42-second encapsulation layer;
43-third encapsulation layer;
101-transistor;
102-storage capacitor;
103-driving structure layer
104-light emitting structure layer;
105-modulationstructure layer;
106-encapsulation structure layer

### DETAILED DESCRIPTION

The embodiments herein may be implemented in a plurality of different forms. Those skilled in the art can easily understand the fact that the embodiments and content may be transformed into various forms without departing from the purpose and scope of the present disclosure. Therefore, the present disclosure should not be interpreted as limited to the content recorded in the following embodiments. Without conflict, the embodiments in the present disclosure and the features in the embodiments may be freely combined with each other.

In the drawings, sometimes the size of the constituent elements, the thickness or region of the layer may be exaggerated for the sake of clarity. Therefore, any implementation of the present disclosure is not necessarily limited to the size illustrated in the drawing, and the shape and size of the components in the drawing do not reflect the actual scale. In addition, the drawings schematically illustrate ideal examples, and any implementation of the present disclosure is not limited to the shape or value illustrated in the drawings.

The ordinal numerals “first”, “second” and “third” herein are set up to avoid the confusion of the constituent elements, not to limit the quantity.

Herein, for the sake of convenience, “middle”, “up”, “down”, “front”, “back”, “vertical”, “horizontal”, “top”, “bottom”, “inside”, “outside” and other words indicating an orientation or positional relationship are used to describe the positional relationship between constituent elements with reference to the drawings, only for the convenience of describing the embodiments and simplifying the description, rather than indicating or implying that the device or element must have a specific orientation or be constructed and operated in a specific orientation, so they should not be understood as limitations to the present disclosure. The positional relationship between the constituent elements may be appropriately changed according to the direction of the described constituent elements. Therefore, it is not limited to the words and sentences described herein, and can be changed appropriately according to the situation.

Herein, unless otherwise specified and limited, the terms “mount”, “connected” and “connect” shall be understood in a broad sense. For example, it may be fixed connection, removable connection, or integrated connection; it may be mechanical connection or electrical connection; it may be direct connection, indirect connection through an intermediate component, or communication inside two components. For those skilled in the art, the meanings of the above terms in the present disclosure may be understood according to the situation.

Herein, a transistor refers to a component which includes at least three terminals, i.e., a gate electrode, a drain electrode and a source electrode. A transistor has a channel region between the drain electrode (or drain electrode terminal, drain region or drain electrode) and the source electrode (or source electrode terminal, source region or source electrode), and the current can flow through the drain electrode, the channel region and the source electrode. Herein, the channel region refers to the region where the current mainly flows.

Herein, a first electrode may be a drain electrode and a second electrode may be a source electrode, or a first electrode may be a source electrode and a second electrode may be a drain electrode. The functions of “source electrode” and “drain electrode” may sometimes be exchanged when transistors of opposite polarity are used or when the current direction changes during circuit operation. Therefore, herein “source electrode” and “drain electrode” may be exchanged with each other.

Herein, “electrical connection” includes the case where constituent elements are connected together by a component having a certain electrical action. As long as electrical signals between the connected constituent elements can be received by “component having a certain electrical action”, there is no special limitation thereto. “Component having a certain electrical action”, for example, may be an electrode or wiring, or a switching element such as a transistor, or other functional element such as a resistor, an inductor or a capacitor.

Herein, “parallel” refers to a state in which an angle formed by two straight lines is more than −10° and less than 10°. Therefore, it also includes a state in which an angle is more than −5° and less than 5°. In addition, “vertical” refers to a state in which an angle formed by two straight lines is more than 80° and less than 100°. Therefore, it also includes a state in which an angle is more than 85° and less than 95°.

Herein, “film” and “layer” may be exchanged. For example, sometimes “conducting layer” may be replaced by “conducting film”. Similarly, sometimes “insulating film” may be replaced by “insulating layer”.

Herein “about” refers to a numerical value within a range of allowable process and measurement errors without strictly limiting the limit.

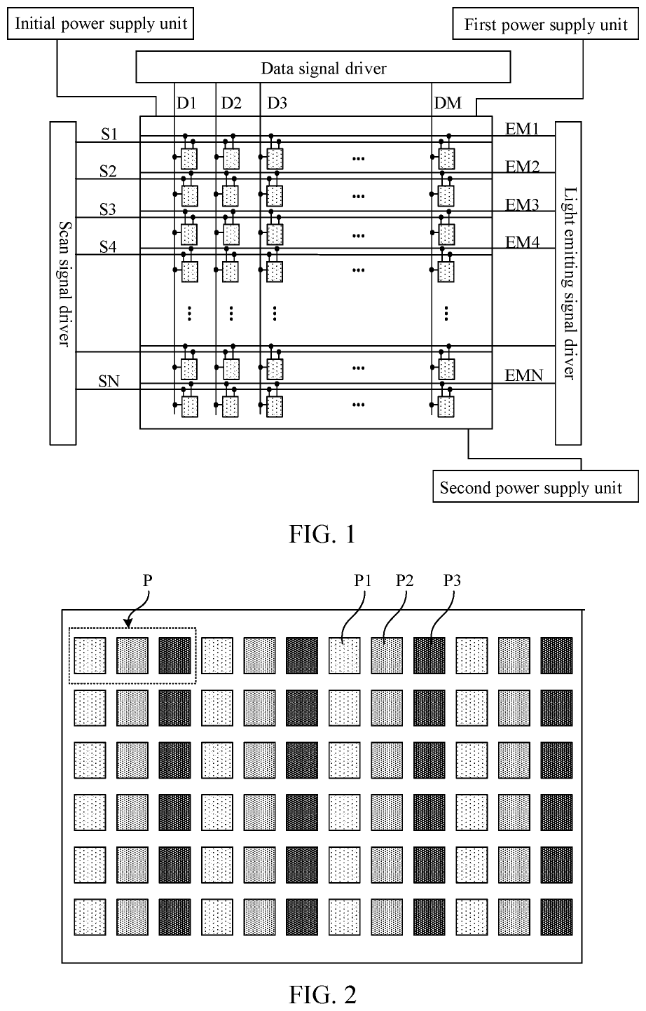

FIG. 1 illustrates a schematic diagram of a structure of an OLED display device. Referring to FIG. 1, the OLED display device may include a scan signal driver, a data signal driver, a light emitting signal driver, an OLED display substrate, a first power supply unit, a second power supply unit and an initial power supply unit. In an exemplary embodiment, the OLED display substrate at least includes a plurality of scan signal lines (S1 to SN), a plurality of data signal lines (D1 to DM) and a plurality of light emitting signal lines (EM1 to EMN). The scan signal driver is configured to sequentially provide scan signals to the plurality of scan signal lines (S1 to SN), the data signal driver is configured to provide data signals to the plurality of data signal lines (D1 to DM), and the light emitting signal driver is configured to sequentially provide light emitting control signals to the plurality of light emitting signal lines (EM1 to EMN). In an exemplary embodiment, the plurality of scan signal lines and the plurality of light emitting signal lines extend along a horizontal direction, and a plurality of data signal lines extend in a vertical direction. The display substrate includes a plurality of sub-pixels. Each sub-pixel includes a pixel driving circuit and a light emitting device. The pixel driving circuit is connected with the scan signal lines, the light emitting control lines and the data signal lines, and is configured to receive data voltage transmitted by the data signal lines and output corresponding current to the light emitting device under the control of the scan signal lines and the light emitting signal lines. The light emitting device is connected with the pixel driving circuit, and is configured to emit light of corresponding brightness in response to the current output by the pixel driving circuit. The first power supply unit, the second power supply unit and the initial power supply unit are respectively configured to provide first power supply voltage, second power supply voltage and initial power supply voltage to the pixel driving circuit through the first power supply lines, the second power supply lines and the initial signal lines.

FIG. 2 illustrates a schematic diagram of a planar structure of a display substrate. Referring to FIG. 2, a display region may include a plurality of pixel units P arranged in an array. At least one of the plurality of pixel units P includes a first sub-pixel P1 emitting first-color light, a second sub-pixel P2 emitting second-color light, and a third sub-pixel P3 emitting third-color light. The first sub-pixel P1, the second sub-pixel P2 and the third sub-pixel P3 each include a pixel driving circuit and a light emitting device. In an exemplary embodiment, the pixel unit P may include a red (R) sub-pixel, a green (G) sub-pixel, and a blue (B) sub-pixel, or may include a red sub-pixel, a green sub-pixel, a blue sub-pixel, and a white (W) sub-pixel, which is not limited in the present disclosure. In an exemplary embodiment, the shape of the sub-pixels in the pixel unit may be a rectangular shape, a diamond, a pentagonal shape, or a hexagonal shape. When the pixel unit includes three sub-pixels, the three sub-pixels may be arranged in parallel horizontally, in parallel vertically or in a triangle shape. When the pixel unit includes four sub-pixels, the four sub-pixels may be arranged in parallel horizontally, in parallel vertically or in a square shape, which is not limited in the present disclosure.

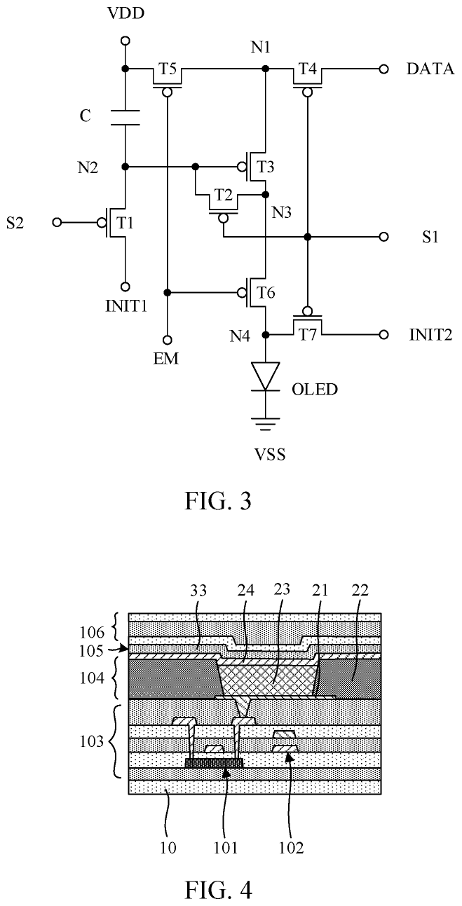

In an exemplary embodiment, the pixel driving circuit may be a 3T1C, 4T1C, 5T1C, 5T2C, 6T1C, or 7T1C structure. FIG. 3 illustrates an equivalent circuit diagram of a pixel driving circuit. Referring to FIG. 3, the pixel driving circuit may include seven switching transistors (first transistor T1 to seventh transistor T7), one storage capacitor C and eight signal lines (data signal line DATA, first scan signal line S1, second scan signal line S2, first initial signal line INIT1, second initial signal line INIT2, first power supply line VSS, second power supply line VDD and light emitting signal line EM). The first initial signal line INIT1 and the second initial signal line INIT2 may be the same signal line.

In an exemplary embodiment, a control electrode of the first transistor T1 is connected with the second scan signal line S2, a first electrode of the first transistor T1 is connected with the first initial signal line INIT1, and a second electrode of the first transistor T1 is connected with a second node N2. A control electrode of the second transistor T2 is connected with the first scan signal line S1, a first electrode of the second transistor T2 is connected with the second node N2, and a second electrode of the second transistor T2 is connected with a third node N3. A control electrode of the third transistor T3 is connected with the second node N2, a first electrode of the third transistor T3 is connected with the first node N1, and a second electrode of the third transistor T3 is connected with the third node N3. A control electrode of the fourth transistor T4 is connected with the first scan signal line S 1, a first electrode of the fourth transistor T4 is connected with the data signal line DATA, and a second electrode of the fourth transistor T4 is connected with the first node N1. A control electrode of the fifth transistor T5 is connected with the light emitting signal line EM, a first electrode of the fifth transistor T5 is connected with the second power supply line VDD, and a second electrode of the fifth transistor T5 is connected with the first node N1. A control electrode of the sixth transistor T6 is connected with the light emitting signal line EM, a first electrode of the sixth transistor T6 is connected with the third node N3, and a second electrode of the sixth transistor T6 is connected with the first electrode of the light emitting device. A control electrode of the seventh transistor T7 is connected with the first scan signal line S 1, a first electrode of the seventh transistor T7 is connected with the second initial signal line INIT2, and a second electrode of the seventh transistor T7 is connected with the first electrode of the light emitting device. A first end of the storage capacitor C is connected with the second power supply line VDD, and a second end of the storage capacitor C is connected with the second node N2.

In an exemplary embodiment, the first transistor T1 to the seventh transistor T7 may be P-type transistors or may be N-type transistors. Using the same type of transistors in the pixel driving circuit can simplify the process flow, reduce the process difficulty of the display panel, and improve the yield of the product. In some possible embodiments, the first transistor T1 to the seventh transistor T7 may include P-type transistors and N-type transistors.

In an exemplary embodiment, the second electrode of the light emitting device is connected with the first power supply line VSS. The signal of the first power supply line VSS is a low-level signal and the signal of the second power supply line VDD is a continuously provided high-level signal. The first scan signal line S1 is a scan signal line in the pixel driving circuit of a current display line, and the second scan signal line S2 is a scan signal line in the pixel driving circuit of a previous display line, that is, for the nth display line, the first scan signal line S1 is S(n) and the second scan signal line S2 is S(n−1). The second scan signal line S2 of the current display line and the first scan signal line S1 of the pixel driving circuit of the previous display line are the same signal line, thus reducing the number of the signal lines of the display panel and realizing the narrow frame of the display panel.

FIG. 4 is a schematic diagram of a sectional structure of a display substrate according to an exemplary embodiment of the present disclosure, illustrating a structure of a sub-pixel of the OLED display substrate. Referring to FIG. 4, on a plane perpendicular to the display substrate, the display substrate may include a driving circuit layer 103 disposed on a base substrate 10, a light emitting structure layer 104 disposed on the side of the driving circuit layer 103 away from the base substrate 10, a modulation structure layer 105 disposed on the side of the light emitting structure layer 104 away from the base substrate 10, and an encapsulation structure layer 106 disposed on the side of the modulation structure layer 105 away from the base substrate 10. In an exemplary embodiment, the driving circuit layer 103 may include a transistor 101 and a storage capacitor 102. In an exemplary embodiment, the light emitting structure layer 104 is a light emitting device that emits light from an organic material under the action of an electric field. The light emitting structure layer 104 may include an anode 21, a pixel definition layer 22, an organic light emitting layer 23 and a cathode 24. A pixel opening exposing the anode 21 is disposed in the pixel definition layer 22, and the organic light emitting layer 23 is disposed between the anode 21 and the cathode 24. In an exemplary embodiment, the modulation structure layer 105 may include a light block layer 33, the light block layer 33 is disposed on the side of the cathode 24 away from the base substrate 10, and the light block layer 33 is configured to block ultraviolet rays from being incident on the pixel definition layer 22. The encapsulation structure layer 106 may include a first encapsulation layer disposed on the side of the light block layer 33 away from the base substrate, a second encapsulation layer disposed on the side of the first encapsulation layer away from the base substrate, and a third encapsulation layer disposed on the side of the second encapsulation layer away from the base substrate. The second encapsulation layer made of an organic material is disposed between the first encapsulation layer and the third encapsulation layer made of an inorganic material, forming a stack structure of inorganic material/organic material/inorganic material.

In an exemplary embodiment, the light block layers 33 may be connected layers, the light block layers 33 of all sub-pixels are connected, and the orthographic projections of the light block layers 33 on the base substrate are continuous, that is, the light block layers 33 are of an entire surface structure.

In an exemplary embodiment, the light block layer 33 may include an ultraviolet absorption layer, and the ultraviolet absorption layer may include an aromatic amine organic matter added with an N or O heteroatom.

In an exemplary embodiment, the thickness of the ultraviolet absorption layer may be greater than 50 nm.

In an exemplary embodiment, the refractive index of the light block layer may be greater than the refractive index of the cathode, and the refractive index of the light block layer may be greater than the refractive index of the first encapsulation layer, so that the light block layer 33 can improve the light extraction efficiency and emergent light intensity of the light emitting device.

In an exemplary embodiment, the refractive index of the light block layer may be about 1.8 to 2.1. For example, the refractive index of the light block layer may be about 1.9.

The process of preparing the display substrate will be exemplarily described below. “Patterning process” mentioned in the present disclosure includes photoresist coating, mask exposure, development, etching, photoresist stripping and so on for metal materials, inorganic materials or transparent conducting materials, and includes organic material coating, mask exposure, development and so on for organic materials. Deposition may be implemented by adopting any one or more of sputtering, evaporation and chemical vapor deposition. Coating may be implemented by adopting any one or more of spray coating, spin coating and inkjet printing, and etching may be implemented by adopting any one or more of dry etching and wet etching, which are not limited in the present disclosure. “Thin film” refers to a layer of thin film formed by a certain material on a base substrate through deposition or other processes. If a “thin film” does not need a patterning process in the whole preparing process, the “thin film” may also be called a “layer”. If a “thin film” needs a patterning process in the whole preparing process, it is called “thin film” before the patterning process and “layer” after the patterning process. A “layer” obtained after a patterning process includes at least one “pattern”. “A and B are disposed in the same layer” in the present disclosure means that A and B are formed at the same time through the same patterning process, and the “thickness” of the film layer is the size of the film layer in a direction perpendicular to the display substrate. In an exemplary embodiment of the present disclosure, “an orthographic projection of A contains an orthographic projection of B” means that the boundary of the orthographic projection of B falls within the boundary range of the orthographic projection of A, or the boundary of the orthographic projection of A overlaps the boundary of the orthographic projection of B.

In an exemplary embodiment, the process of preparing the display substrate includes the following operations.

(1) A base substrate 101 is formed on a glass carrier plate. In an exemplary embodiment, forming a base substrate on a glass carrier plate may include: coating a first flexible material thin film on a glass carrier plate 1 and forming a first flexible layer after curing into a film; coating a second flexible material thin film on the surface of the side of the first flexible layer away from the glass carrier plate, and forming a second flexible layer after curing into a film; coating a third flexible material thin film on the surface of the side of the second flexible layer away from the glass carrier plate, forming a third flexible layer after curing into a film, and forming a flexible base substrate on the glass carrier plate. The base substrate includes a first flexible layer, a second flexible layer and a third flexible layer which are stacked. In an exemplary embodiment, the first flexible layer, the second flexible layer and the third flexible layer may be made of the same material, or different materials. In some possible embodiments, the material of the first flexible layer includes pressure-sensitive adhesive, and the materials of the second flexible layer and the third flexible layer include polyimide.

In another exemplary embodiment, forming a base substrate on a glass carrier plate 1 may include: firstly coating a first flexible material thin film on a glass carrier plate, and forming a first flexible layer after curing into a film; then depositing a first inorganic material thin film on the first flexible layer to form a first inorganic layer covering the first flexible layer; then depositing an amorphous silicon film on the first inorganic layer to form an amorphous silicon layer covering the first inorganic layer; then coating a second flexible material thin film on the amorphous silicon layer, and forming a second flexible layer after curing into a film; then depositing a second inorganic material thin film on the second flexible layer to form a second barrier layer covering the second flexible layer, and forming a flexible base substrate on the glass carrier plate. The base substrate includes a first flexible layer, a first inorganic layer, a semiconductor layer, a second flexible layer and a second inorganic layer which are stacked. In an exemplary embodiment, the materials of the first, second and third flexible material thin films may be polyimide (PI), polyethylene terephthalate (PET), Pressure Sensitive Adhesive (PSA) or surface-treated polymer flexible film, and the materials of the first and second inorganic material thin films may be silicon nitride (SiNx) or silicon oxide (SiOx), which are used to improve the water oxygen resistance of the base substrate. The first and second inorganic layers are called first and second barrier layers, and the material of the semiconductor layer may be amorphous silicon (a-si).

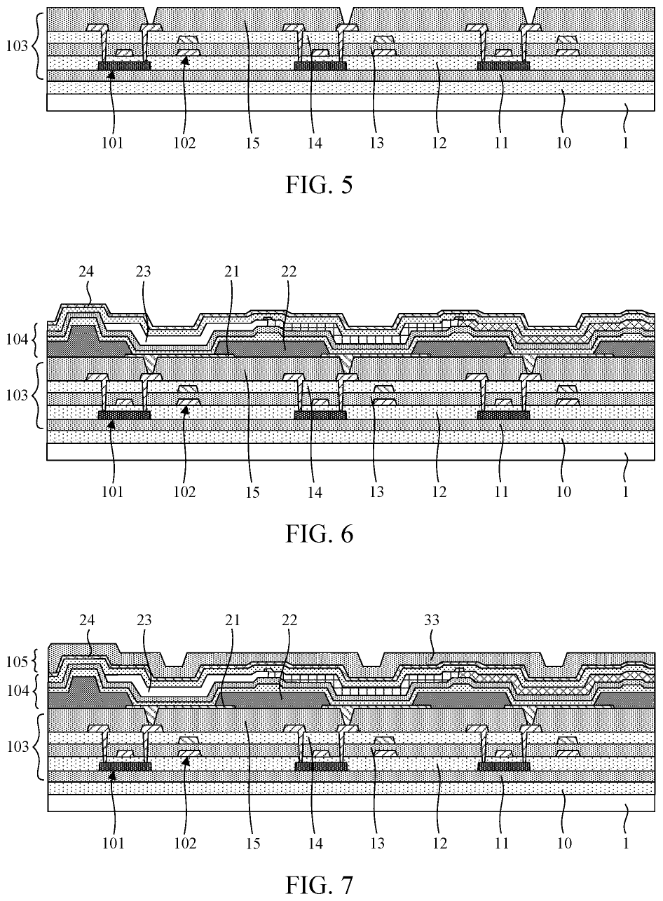

(2) A driving structure layer pattern is formed on the base substrate, referring to FIG. 5. In an exemplary embodiment, the driving structure layer may include a plurality of transistors and storage capacitors forming a pixel driving circuit. FIG. 5 illustrates three sub-pixels. The driving structure layer of each sub-pixel is illustrated by taking one transistor 101 and one storage capacitor 102 as an example. In an exemplary embodiment, the process of forming the driving structure layer may include the following operations:

A first insulating thin film and a semiconductor layer thin film are sequentially deposited on a base substrate 10, and the semiconductor layer thin film is patterned through a patterning process to form a first insulating layer 11 covering the entire base substrate 10 and a semiconductor layer pattern disposed on the first insulating layer 11. The semiconductor layer pattern at least includes an active layer disposed in each sub-pixel.

Then, a second insulating thin film and a first metal thin film are deposited sequentially, and the first metal thin film is patterned through a patterning process to form a second insulating layer 12 covering the semiconductor layer pattern and a first metal layer pattern disposed on the second insulating layer 12. The first metal layer pattern at least includes a gate electrode and a first capacitor electrode disposed in each sub-pixel.

Then, a third insulating thin film and a second metal thin film are deposited sequentially, and the second metal thin film is patterned through a patterning process to form a third insulating layer 13 covering the first metal layer and a second metal layer pattern disposed on the third insulating layer 13. The second metal layer pattern at least includes a second capacitor electrode disposed in each sub-pixel. The position of the second capacitor electrode corresponds to the position of the first capacitor electrode.

Then, a fourth insulating thin film is deposited, and the fourth insulating thin film is patterned through a patterning process to form a fourth insulating layer 14 pattern covering the second metal layer. The fourth insulating layer 14 is provided with a plurality of via patterns. The plurality of via patterns at least include two first vias disposed in each sub-pixel, and the positions of the two first vias correspond to the positions of the two ends of the active layer respectively, and the fourth insulating layer 14, the third insulating layer 13 and the second insulating layer 12 in the two first vias are etched to expose the surface of the active layer.

Then, a third metal thin film is deposited, and the third metal thin film is patterned through a patterning process to form a third metal layer pattern on the fourth insulating layer 14. The third metal layer pattern at least includes a source electrode and a drain electrode disposed in each sub-pixel, and the source electrode and the drain electrode are respectively connected with the active layer through the first vias, so that a conducting channel is formed between the source electrode and the drain electrode.

Then, a planarization thin film is coated to form a fifth insulating layer 15 covering the entire base substrate 10, a via pattern is formed on the fifth insulating layer 15 through a patterning process, the via pattern at least includes a second via disposed in each sub-pixel, and the fifth insulating layer 15 in the second via is removed to expose the surface of the drain electrode. In an exemplary embodiment, the fifth insulating layer 15 may be a planarization (PLN) layer, the surface of the side of the planarization layer away from the base substrate 10 is a flat and straight surface, and the planarization layer may be made of resin or other materials.

So far, the formed structure includes the base substrate 10 disposed on the glass carrier plate 1 and the driving structure layer 103 disposed on the base substrate 10, referring to FIG. 5. The active layer, the gate electrode, the source electrode and the drain electrode form a transistor 101, and the first capacitor electrode and the second capacitor electrode form a storage capacitor 102. In an exemplary embodiment, the transistor may be a driving transistor in a pixel driving circuit, and the driving transistor may be a Thin Film Transistor (TFT).

In an exemplary embodiment, the first insulating layer, the second insulating layer, the third insulating layer and the fourth insulating layer may be made of any one or more of silicon oxide (SiOx), silicon nitride (SiNx) and silicon nitride (SiON), and may be a single layer, multiple layers or a composite layer. The first insulating layer is called a buffer layer, which is used to improve the water oxygen resistance of the base substrate. The second insulating layer and the third insulating layers are called gate insulating (GI) layers. The fourth insulating layer is called an interlayer insulating (ILD) layer. The first metal thin film, the second metal thin film and the third metal thin film may be made of a metal material, such as any one or more of silver (Ag), copper (Cu), aluminum (Al), titanium (Ti) and molybdenum (Mo), or an alloy material of the above metals, such as aluminum-neodymium alloy (AlNd) or molybdenum-niobium alloy (MoNb), which may be a single-layer structure or multi-layer composite structure, such as Ti/Al/Ti. The active layer thin film may be made of an amorphous indium gallium zinc oxide (a-IGZO), zinc nitride (ZnO), indium zinc tin oxide (IZTO), amorphous silicon (a-Si), polycrystalline silicon (p-Si), hexathiophene, polythiophene and other materials, that is, the present disclosure is applicable to transistors manufactured based on oxide technology, silicon technology and organic matter technology.

(3) A light emitting structure layer is formed on the driving structure layer, referring to FIG. 6. In an exemplary embodiment, forming a light emitting structure layer on the driving structure layer may include the following operations:

A conducting thin film is deposited on the base substrate on which the above pattern is formed, and the conducting thin film is patterned through a patterning process to form a conducting layer pattern. The conducting layer pattern at least includes an anode 21 disposed in each sub-pixel, and the anode 21 is connected with the drain electrode of the first transistor 101 through a second via. In an exemplary embodiment, the conducting thin film may be made of a single-layer transparent conducting material, such as indium tin oxide (ITO) or indium zinc oxide (IZO), or the conducting thin film may be made of a metal material and a transparent conducting material of a composite layer, such as Ag/ITO, Ag/IZO or ITO/Ag/ITO, the thickness of the metal material in the composite layer may be about 80 nm to 100 nm, and the thickness of the transparent conducting material in the composite layer may be about 5 nm to 20 nm, so that the average reflectivity of the anode in the visible region is about 85%-95%.

A pixel definition thin film is coated on the base substrate on which the above pattern is formed, and the pixel definition thin film is subject to mask exposure and development through a patterning process to form a pixel definition layer (PDL) 22. In each sub-pixel, the pixel definition layer 22 is provided with a pixel opening, and the pixel definition thin film in the pixel opening is developed to expose the surface of the anode 21. In an exemplary embodiment, in a plane parallel to the base substrate, the shape of the pixel opening may be a square shape, a rectangular shape, a circular shape, an elliptical shape or a hexagonal shape, and may be set according to the actual needs, which is not limited in the present disclosure. In an exemplary embodiment, the pixel definition thin film may be made of materials such as polyimide, acrylic or polyethylene terephthalate, and the formed pixel definition layer 22 may include a post spacer (PS) pattern.

An organic light emitting layer 23 and a cathode 24 are sequentially formed on the base substrate on which the above pattern is formed, the organic light emitting layer 23 is connected with the anode 21 in the pixel opening, the cathode 24 is formed on the organic light emitting layer 23 and connected with the organic light emitting layer 23, and the cathodes 24 of a plurality of sub-pixels are of an integrated structure. In an exemplary embodiment, the cathode may be made of a metal material, the metal material may be magnesium (Mg), silver (Ag) or aluminum (Al), or an alloy material, such as an Mg:Ag alloy, the Mg:Ag ratio is about 9:1 to 1:9, and the thickness of the cathode may be about 10 nm to 20 nm.

Thus, the light emitting structure layer 104 pattern is formed on the driving structure layer 103, referring to FIG. 6. In an exemplary embodiment, the anode 21, the organic light emitting layer 23 and the cathode 24 in the light emitting structure layer 104 form an OLED light emitting device. The organic light emitting layer 23 is disposed between the anode 21 and the cathode 24. Holes and electrons are injected into the organic light emitting layer 23 from the anode 21 and the cathode 24 respectively. When the electrons and the holes meet in the organic light emitting layer 23, the electrons and the holes recombine to produce excitons, these excitons emit light while changing from the excited state to the ground state, and the organic light emitting layer 23 emits light of corresponding gray scale.

In an exemplary embodiment, the organic light emitting layer 23 may include an Emitting Layer (EML) and any one or more of the following layers: a Hole Injection Layer (HIL), a Hole Transport Layer (HTL), an Electron Block Layer (EBL), a Hole Block Layer (HBL), Electron Transport Layer (ETL) and an Electron Injection Layer (EIL).

In an exemplary embodiment, the light emitting layers of different sub-pixels are different. For example, a red light emitting device includes a red light emitting layer, a green light emitting device includes a green light emitting layer, and a blue light emitting device includes a blue light emitting layer. In order to reduce the difficulty of the process and improve the yield, the hole injection layer and hole transport layer on one side of the light emitting layer may be connected layers, and the electron injection layer and the electron transport layer on the other side of the light emitting layer may be connected layers. In an exemplary embodiment, any one or more of the hole injection layer, hole transport layer, electron injection layer and electron transport layer may be formed through a one-time process (one-time evaporation process or one-time inkjet printing process), which, however, are isolated by the formed film layer surface segment difference or by means of surface treatment. For example, any one or more of the hole injection layers, hole transport layers, electron injection layers and electron transport layers corresponding to adjacent sub-pixels may be isolated. In an exemplary embodiment, the organic light emitting layer may be formed by adopting Fine Metal Mask (FMM) or open mask evaporation or by adopting an inkjet process.

In an exemplary embodiment, the organic light emitting layer may be formed through the following method. After the pixel definition layer is formed, a hole injection layer and a hole transport layer are evaporated sequentially by using an open mask, and a connected layer of the hole injection layer and the hole transport layer is formed on the display substrate, that is, the hole injection layers of all sub-pixels are connected, and the hole transport layers of all sub-pixels are connected. The respective area of the hole injection layer and the hole transport layer is approximately the same and the thicknesses is different. Then, an electronic block layer and a red light emitting layer, an electronic block layer and a green light emitting layer, and an electronic block layer and a blue light emitting layer are respectively evaporated on different sub-pixels by using a fine metal mask. The electronic block layers and the light emitting layers of adjacent sub-pixels may overlap a small amount (for example, the overlap part accounts for less than 10% of the area of the respective light emitting layer pattern), or may be isolated. Then, a hole block layer, an electron transport layer, an electron injection layer and a cathode are evaporated subsequently by using an open mask, and a connected layer of the hole block layer, the electron transport layer, the electron injection layer and the cathode is formed on the display substrate, that is, the hole block layers of all sub-pixels are connected, the electron transport layers of all sub-pixels are connected, the electron injection layers of all sub-pixels are connected, and the cathodes of all sub-pixels are connected.

In an exemplary embodiment, an orthographic projection of one or more of the hole injection layers, the hole transport layers, the hole block layers, the electron transport layers, the electron injection layers and the cathodes on the base substrate is continuous. In some examples, at least one of the hole injection layers, the hole transport layers, the hole block layers, the electron transport layers, the electron injection layers and the cathodes in at least one row or column of sub-pixels is connected. In some examples, at least one of the hole injection layers, the hole transport layers, the hole block layers, the electron transport layers, the electron injection layers and the cathodes of a plurality of sub-pixels is connected.

In an exemplary embodiment, since the hole block layers are connected layers and the light emitting layers of different sub-pixels are isolated, the orthographic projection of the hole block layer on the substrate contains the orthographic projection of the light emitting layer on the substrate, and the area of the hole block layer is greater than the area of the light emitting layer. Since the hole block layers are connected layers, the orthographic projection of the hole block layer on the substrate contains at least the orthographic projections of the light emitting regions of two sub-pixels on the substrate. In an exemplary embodiment, the orthographic projections of the light emitting layers of at least partial sub-pixels on the substrate overlap with the orthographic projection of the pixel driving circuit on the substrate.

In an exemplary embodiment, the electron block layer serves as a microcavity adjustment layer between the hole transport layer and the light emitting layer, so that the thickness of the organic light emitting layer between the cathode and the anode can be designed according to the optical path requirement of the optical micro resonant cavity to obtain the optimal emergent light intensity and color.

In an exemplary embodiment, the light emitting layer may include a host material and a dopant material doped into the host material. The doping ratio of the dopant material in the light emitting layer is 1% to 20%. Within the doping ratio range, on the one hand, the host material in the light emitting layer can effectively transfer the exciton energy to the dopant material in the light emitting layer to excite the dopant material in the light emitting layer to emit light; on the other hand, the host material in the light emitting layer “dilutes” the dopant material in the light emitting layer, thus effectively improving the fluorescence quenching caused by the collision between molecules of the dopant material in the light emitting layer and between energy, and improving the luminous efficiency and service life of the device. In an exemplary embodiment, the doping ratio refers to the ratio of the mass of the dopant material to the mass of the light emitting layer, that is, the mass percentage. In an exemplary embodiment, the host material and the dopant material may be evaporated together through a multi-source evaporation process, so that the host material and the dopant material are evenly dispersed in the light emitting layer. The doping ratio may be adjusted and controlled by controlling the evaporation rate of the dopant material in the evaporation process, or by controlling the evaporation rate ratio of the host material to the dopant material.

In an exemplary embodiment, the hole injection layer may be made of an inorganic oxide, such as molybdenum oxide, titanium oxide, vanadium oxide, rhenium oxide, ruthenium oxide, chromium oxide, zirconium oxide, hafnium oxide, tantalum oxide, silver oxide, tungsten oxide or manganese oxide, or may be made of a p-type dopant of an electron absorption system and a dopant of a hole transport material. In an exemplary embodiment, the thickness of the hole injection layer may be about 5 nm to 20 nm.

In an exemplary embodiment, the hole transport layer may be made of a material with high hole mobility, such as an aromatic amine compound, and its substituent group may be carbazole, methylfluorene, spirofluorene, dibenzothiophene or furan. In an exemplary embodiment, the thickness of the hole transport layer may be about 60 nm to 150 nm.

In an exemplary embodiment, the electron block layer may be made of an aromatic amine compound with hole transport characteristics, and its substituent group may be carbazole, methylfluorene, spirofluorene, dibenzothiophene or furan. In an exemplary embodiment, the thickness of the electron block layer may be about 5 nm to 20 nm.

In an exemplary embodiment, the light emitting layer may include a light emitting host material and a light emitting dopant material. The light emitting host material may be a bipolar single host, or a double host formed by blending a hole type dopant and an electronic type dopant. The light emitting dopant material may be a phosphorescent material, a fluorescent material, a delayed fluorescent material, or the like. In an exemplary embodiment, the thickness of the light emitting layer may be about 10 nm to 25 nm.

In an exemplary embodiment, the hole block layer and the electron transport layer may be made of aromatic heterocyclic compounds, for example, imidazole derivatives such as benzimidazole derivatives, imidazolopyridine derivatives, and benzimidazolophenanthridine derivatives; azine derivatives such as pyrimidine derivatives and triazine derivatives; compounds containing a nitrogen-containing six-membered ring structure such as quinoline derivatives, isoquinoline derivatives and phenanthroline derivatives (also including compounds with a phosphine oxide substituent group on a heterocyclic ring). In an exemplary embodiment, the thickness of the hole block layer may be about 5 nm to 15 nm, and the thickness of the electron transport layer may be about 20 nm to 50 nm.

In an exemplary embodiment, the electron injection layer may be made of an alkali metals or metals, for example, materials such as lithium fluoride (LiF), ytterbium (Yb), magnesium (Mg) or calcium (Ca), or compounds of these alkali metals or metals. In an exemplary embodiment, the thickness of the electron injection layer may be about 0.5 nm to 2 nm.

(4) A modulation structure layer is formed on the light emitting structure layer, referring to FIG. 7. In an exemplary embodiment, forming a modulation structure layer on the light emitting structure layer may include: evaporating light block layers 33 by using an open mask, forming a connected layer of the light block layers 33 on the display substrate, that is, the light block layers 33 of all sub-pixels are connected.

So far, the modulation structure layer 105 pattern has been formed on the light emitting structure layer 104, and the modulation structure layer 105 includes a light block layer 33, referring to FIG. 7. In an exemplary embodiment, the light block layer 33 is configured to block ultraviolet rays from being incident on the pixel definition layer, thus improving the service life of the display substrate.

In an exemplary embodiment, the refractive index of the light block layer 33 may be greater than the refractive index of the cathode, and the refractive index of the light block layer 33 may be greater than the refractive index of the first encapsulation layer in the subsequently formed encapsulation structure layer, so that the light block layer 33 can improve the light extraction efficiency and the emergent light intensity of the light emitting device.

In an exemplary embodiment, the refractive index of the light block layer 33 may be about 1.8 to 2.1. For example, the refractive index of the light block layer 33 may be about 1.9.

In an exemplary embodiment, the light block layer 33 may be an ultraviolet absorption layer.

In an exemplary embodiment, the ultraviolet absorption layer may include an aromatic amine organic matter added with an N or O heteroatom, and the added N or O heteroatom can adjust the absorption coefficient of the ultraviolet absorption layer for light at different bands. In an exemplary embodiment, the aromatic amine organic matter added with the N or O heteroatom may include N, N′-diphenyl-N, N′-di (3-tolyl)-1,1′-biphenyl-4,4′-diamine (TPD), or may include N, N′-diphenyl-N, N′-di (1-naphthyl)-1,1′-biphenyl-4,4′-diamine (NPB).

In an exemplary embodiment, the thickness of the ultraviolet absorption layer may be greater than 50 nm to effectively absorb ultraviolet rays.

In an exemplary embodiment, the thickness of the ultraviolet absorption layer may be about 50 nm to 100 nm. For example, the thickness of the ultraviolet absorption layer may be about 80 nm.

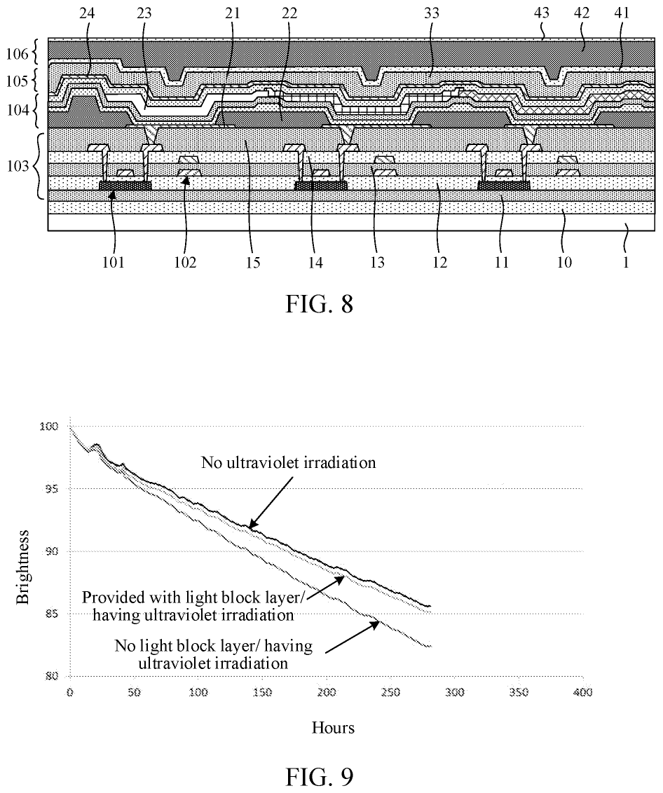

(5) An encapsulation structure layer is formed on the modulation structure layer, referring to FIG. 8. In an exemplary embodiment, forming an encapsulation structure layer on the modulation structure layer may include depositing a first inorganic thin film by using an open mask to form a first encapsulation layer. Then, an organic material is inkjet printed on the first encapsulation layer through an inkjet printing process, and a second encapsulation layer is formed after curing into a film. Then, a second inorganic thin film is deposited by using an open mask to form a third encapsulation layer. In an exemplary embodiment, the first encapsulation layer and the third encapsulation layer may be made of any one or more of silicon oxide (SiOx), silicon nitride (SiNx) and silicon oxynitride (SiON), and may be a single layer, a multilayer or a composite layer, and the second encapsulation layer may be made of a resin material.

So far, the encapsulation structure layer 106 pattern is formed on the modulation structure layer 105, referring to FIG. 8. The encapsulation structure layer 106 includes a first encapsulation layer, a second encapsulation layer and a third encapsulation layer which are stacked, so as to form a stacked structure of inorganic material/organic material/inorganic material. The organic material layer is disposed between the two inorganic material layers to ensure that external water vapor cannot enter the light emitting structure layer. In an exemplary embodiment, the thickness of the first encapsulation layer may be about 800 nm to 1200 nm, the thickness of the second encapsulation layer may be about 6000 nm to 10000 nm, and the thickness of the third encapsulation layer may be about 600 nm to 800 nm.

In an exemplary embodiment, the refractive index of the first encapsulation layer may be about 1.6 to 1.9, such as 1.78, that is, the refractive index of the first encapsulation layer is less than the refractive index of the light block layer, so that the refractive index of the light block layer is greater than the refractive indexes of the cathode and the first encapsulation layer respectively. The light block layer has a light extraction function to improve the light extraction efficiency and the emergent light intensity of the light emitting device. The refractive index of the second encapsulation layer may be about 1.4 to 1.7, such as 1.53. The refractive index of the third encapsulation layer may be about 1.7 to 2.0, such as 1.86.

In an exemplary embodiment, after the encapsulation structure layer is formed, a touch structure layer (TSP) may be formed on the encapsulation structure layer, which may include a touch electrode layer, or include a touch electrode layer and a touch insulating layer.

In an exemplary embodiment, when preparing the flexible display substrate, the process of preparing the display substrate may further include stripping a glass carrier plate 1, attaching a back film, cutting and other processes, which are not limited in the present disclosure.

The structure and its preparing process in the exemplary embodiment of the present disclosure are only exemplarily described. In an exemplary embodiment, the corresponding structure may be changed and the patterning process may be added or reduced according to the actual needs. For example, the transistor in the driving structure layer may be a top gate structure, a bottom gate structure, a single gate structure, or a double gate structure. For another example, other film layer structures, electrode structures or lead structures may be further disposed in the driving structure layer and the light emitting structure layer. For another example, the base substrate may be a glass base substrate, which is not limited in the present disclosure.

After decades of development, although the OLED display technology has made great technological breakthroughs, has been successfully commercialized and has shown great potential in high-tech display fields such as flexibility and transparency, it still has the problem of low service life. In an OLED display device, a display substrate includes a driving circuit layer, a light emitting structure layer and an encapsulation structure layer sequentially disposed on a base substrate, and a first encapsulation layer of the encapsulation structure layer covers the cathode of the light emitting structure layer. The practical application shows that the display device with this structure has the problems of low light extraction efficiency and short service life. Especially in the environment with ultraviolet radiation, the service life decreases significantly. The service life of the OLED display device generally refers to the time required for the brightness of the OLED display device to decrease from 100% to 95%. It is commonly expressed by LT95. Since the service life curve follows the multi-exponential attenuation model, the service life of the OLED display device can be estimated according to LT95. The experimental study shows that the LT95 service life of the display device is reduced by about 60% in the ultraviolet irradiation environment compared with the LT95 service life of the display device without ultraviolet irradiation. The low service life in the ultraviolet irradiation environment makes the OLED display device unable to be used in some areas or some harsh environments, which seriously restricts the application range of OLED display devices.

Further research shows that the shortened service life of the OLED display device in the ultraviolet irradiation environment is due to outgassing in the pixel definition layer in the light emitting structure layer. During preparing the display substrate, after the pixel definition layer is formed, the display substrate needs to be cleaned, baked and cooled, and then the evaporation process of the organic light emitting layer is carried out. In the process of baking the display substrate in the N₂ environment, the compound structure in the pixel definition layer of the polyimide material changes to produce a compound with a new structure, as expressed by the following chemical formula:

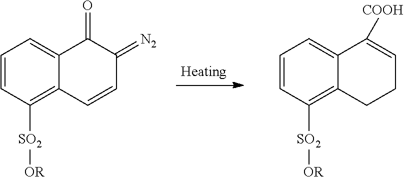

The compound with the new structure will produce sulfur dioxide (SO₂) and other gases under ultraviolet irradiation, that is, outgassing occurs, as expressed by the following chemical formula:

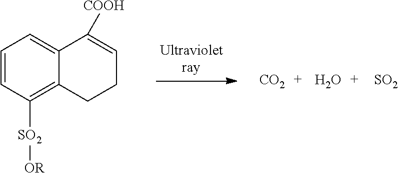

After SO₂ and other gases generated by outgassing in the pixel definition layer under ultraviolet irradiation enter the organic light emitting layer, since the organic light emitting material is particularly sensitive to water, oxygen and SO₂, these gases will destroy the organic light emitting material and cause the failure of the organic light emitting layer, resulting in a significant decline in the service life of the OLED display device in the ultraviolet irradiation environment.

In this exemplary embodiment of the present disclosure, the modulation structure layer is disposed between the light emitting structure layer and the encapsulation structure layer, and the modulation structure layer includes the light block layer that reduces the incidence of ultraviolet rays into the pixel definition layer. In the ultraviolet irradiation environment, the light block layer can effectively absorb most of the ultraviolet rays, thus effectively reducing the intensity of ultraviolet rays entering the pixel definition layer, avoiding or reducing the outgassing of the pixel definition layer, avoiding or slowing down the failure of the organic light emitting layer, and effectively improving the service life of the OLED display device in the ultraviolet irradiation environment.

FIG. 9 illustrates a schematic diagram of service life simulation results of a display substrate according to an exemplary embodiment of the present disclosure. Referring to FIG. 9, for the display substrate without a light block layer, the service life in the ultraviolet irradiation environment is significantly lower than the service life in the absence of ultraviolet irradiation. For the display substrate with a light block layer, the service life in the ultraviolet irradiation environment is significantly higher than the service life of the display substrate without the light block layer, and the service life of the display substrate with a light block layer in the ultraviolet irradiation environment is basically the same as the service life of the display substrate without ultraviolet irradiation. Accordingly, it can be seen that the display substrate in this exemplary embodiment of the present disclosure effectively improves the service life of the OLED display device by disposing the light block layer.

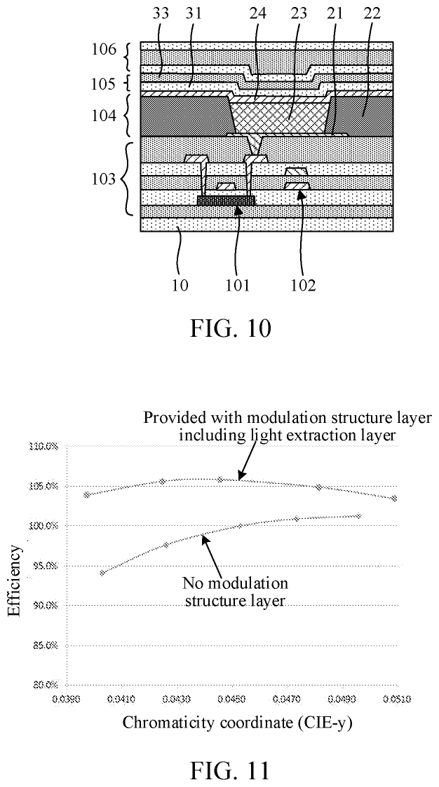

FIG. 10 is a schematic diagram of a sectional structure of another display substrate according to an exemplary embodiment of the present disclosure, illustrating a structure of a sub-pixel of an OLED display substrate. Referring to FIG. 10, in a plane perpendicular to the display substrate, the display substrate may include a driving circuit layer 103 disposed on a base substrate 10, a light emitting structure layer 104 disposed on the side of the driving circuit layer 103 away from the base substrate 10, a modulation structure layer 105 disposed on the side of the light emitting structure layer 104 away from the base substrate 10, and an encapsulation structure layer 106 disposed on the side of the modulation structure layer 105 away from the base substrate 10. In an exemplary embodiment, the structures of the driving circuit layer 103, the light emitting structure layer 104 and the encapsulation structure layer 106 may be similar to the structure in the above embodiment. In an exemplary embodiment, the modulation structure layer 105 may include a light extraction layer 31 and a light block layer 33 which are stacked. The light extraction layer 31 is disposed on the side of a cathode 24 in the light emitting structure layer 104 away from the base substrate 10 and is configured to extract light. The light block layer 33 is disposed on the side of the light extraction layer 31 away from the base substrate 10 and is configured to block ultraviolet rays from being incident on the pixel definition layer 22.

In an exemplary embodiment, both the light extraction layer 31 and the light block layer 33 may be connected layers, the light extraction layers 31 and the light block layers 33 of all sub-pixels are connected, and orthographic projections of the light extraction layers 31 and the light block layers 33 on the base substrate are continuous, that is, the light block layers 33 are of an entire surface structure.

In an exemplary embodiment, the light extraction layer 31 may be referred to as a Capping Layer (CPL), and configured to extract light, adjust the reflectivity and transmittance of the emergent light, and adjust the length of the optical micro resonant cavity.

In an exemplary embodiment, the material of the light extraction layer 31 may be an aromatic amine organic matter.

In an exemplary embodiment, the thickness of the light extraction layer 31 may be about 60 nm to 100 nm. For example, the thickness of the light extraction layer 31 may be about 80 nm.

In an exemplary embodiment, the refractive index of the light extraction layer may be greater than the refractive indexes of the cathode and the light block layer, so as to facilitate light extraction and improvement of light extraction efficiency.

In an exemplary embodiment, the refractive index of the light block layer may be less than the refractive index of the first encapsulation layer, so as to facilitate light extraction and improvement of light extraction efficiency.

In an exemplary embodiment, the refractive index of the light extraction layer may be about 1.7 to 2.0, and the refractive index of the light block layer may be about 1.6 to 1.9. For example, the refractive index of the light extraction layer may be about 1.8, and the refractive index of the light block layer may be about 1.7.

In an exemplary embodiment, the light block layer may adopt an ultraviolet absorption layer, and its refractive index may be adjusted by adjusting the added N heteroatom or O heteroatom.

In an exemplary embodiment, the process of preparing the display substrate in this embodiment is basically similar to that in the above embodiment, except that forming the modulation structure layer on the light emitting structure layer may include: subsequently evaporating a light extraction layer 31 and a light block layer 33 by using an open mask, and forming a connected layer of the light extraction layer 31 and the light block layer 33 on the display substrate, that is, the light extraction layers 31 and the light block layers 33 of all sub-pixels are connected.

In this exemplary embodiment of the present disclosure, the modulation structure layer is disposed between the light emitting structure layer and the encapsulation structure layer, and the modulation structure layer includes the light extraction layer and the light block layer, thus not only effectively improving the service life of the OLED display device in the ultraviolet irradiation environment, but also effectively improving the light extraction efficiency of the OLED display device. When light waves (electromagnetic waves) are incident on an interface between metal and dielectric, free electrons on the metal surface oscillate collectively, the electromagnetic waves are coupled with the free electrons on the metal surface to form near-field electromagnetic waves propagating along the metal surface. If the oscillation frequency of the electrons is consistent with the frequency of the incident light waves, resonance will occur. In the resonant state, the energy of the electromagnetic field is effectively transformed into the collective vibration energy of the free electrons on the metal surface. At this time, a special electromagnetic mode is formed: the electromagnetic field is limited to a small range on the metal surface and enhanced. This phenomenon is called Surface Plasmon Polariton (SPP) effect, which will reduce the light extraction efficiency. In this exemplary embodiment of the present disclosure, the light extraction layer is disposed on the cathode, thus effectively eliminating the SPP effect and improving the light extraction efficiency. In addition, since the cathode has a semi-transmitting and semi-reflecting effect on the emergent light, the light extraction layer is disposed on the cathode, thus effectively adjusting the reflectivity and transmittance of the outgoing light, effectively adjusting the length of the optical micro resonant cavity, and improving the emergent light intensity. In this exemplary embodiment of the present disclosure, the refractive index of the light extraction layer is set to be greater than the refractive indexes of the cathode and the light block layer, so that the stacked light extraction layer and light block layer effectively improve the light extraction efficiency and the emergent light intensity.

FIG. 11 illustrates a schematic diagram of light extraction efficiency simulation results of a display substrate according to an exemplary embodiment of the present disclosure. Referring to FIG. 11, compared with a display substrate with a conventional structure (a modulation structure layer including a light extraction layer is not disposed), the display substrate with the modulation structure layer including the light extraction layer and the light block layer in this exemplary embodiment of the present disclosure has significantly improved light extraction efficiency. Accordingly, it can be seen that the display substrate in the exemplary embodiment of the present disclosure not only effectively improves the service life of the OLED display device in the ultraviolet irradiation environment, but also effectively improves the light extraction efficiency of the OLED display device.

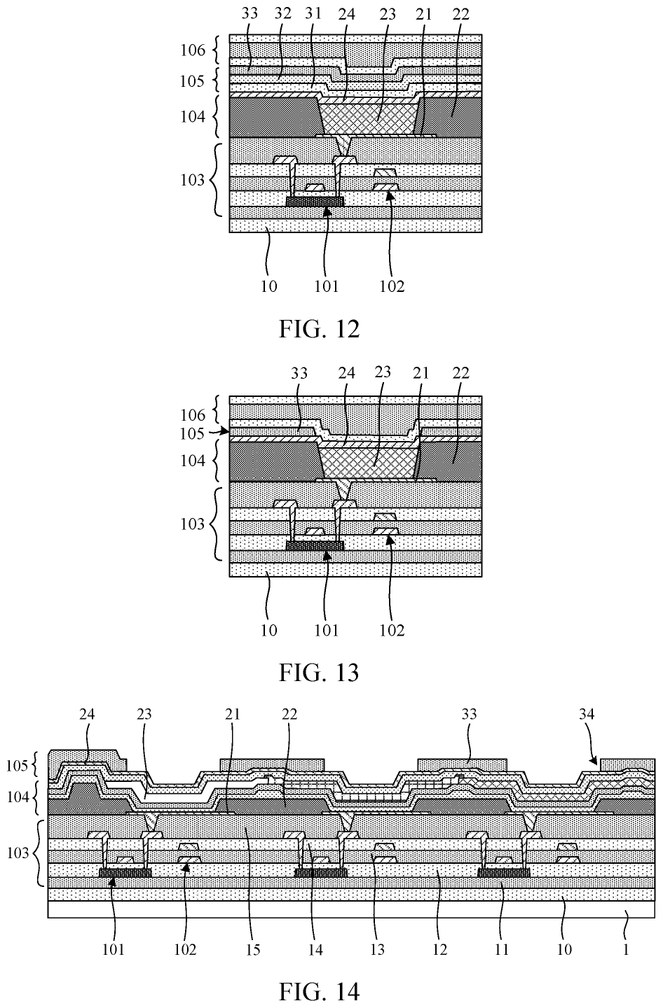

FIG. 12 is a schematic diagram of a sectional structure of another display substrate according to an exemplary embodiment of the present disclosure, illustrating a structure of a sub-pixel of an OLED display substrate. Referring to FIG. 12, in a plane perpendicular to the display substrate, the display substrate may include a driving circuit layer 103 disposed on a base substrate 10, a light emitting structure layer 104 disposed on the side of the driving circuit layer 103 away from the base substrate 10, a modulation structure layer 105 disposed on the side of the light emitting structure layer 104 away from the base substrate 10, and an encapsulation structure layer 106 disposed on the side of the modulation structure layer 105 away from the base substrate 10. In an exemplary embodiment, the structures of the driving circuit layer 103, the light emitting structure layer 104 and the encapsulation structure layer 106 may be similar to those in the above embodiments. In an exemplary embodiment, the modulation structure layer 105 may include a light extraction layer 31, a protective layer 32 and a light block layer 33 which are stacked. The light extraction layer 31 is disposed on the side of a cathode 24 in the light emitting structure layer 104 away from the base substrate 10 and configured to extract light. The protective layer 32 is disposed on the side of the light extraction layer 31 away from the base substrate 10 and configured to protect the light extraction layer 31. The light block layer 33 is disposed on the side of the protective layer 32 away from the base substrate 10 and configured to block ultraviolet rays from being incident on the pixel definition layer 22.

In an exemplary embodiment, the light extraction layer 31, the protective layer 32 and the light block layer 33 may be connected layers, the light extraction layers 31, the protective layers 32 and the light block layers 33 of all sub-pixels are connected, and orthographic projections of the light extraction layers 31, the protective layers 32 and the light block layers 33 on the base substrate are continuous, that is, the light block layers 33 are of an entire surface structure.

In an exemplary embodiment, the materials and structures of the light extraction layer 31 and the light block layer 33 may be similar to those of the structures in the above embodiment.

In an exemplary embodiment, the protective layer 32 is configured to protect the light extraction layer 31 and improve the light extraction efficiency. The protective layer 32 may be made of alkali metals or metals, or compounds of these alkali metals or metals, such as lithium fluoride (LiF).

In an exemplary embodiment, the thickness of the protective layer 32 may be about 60 nm to 100 nm. For example, the thickness of the protective layer 32 may be about 80 nm.

In an exemplary embodiment, the refractive index of the light extraction layer may be greater than the refractive indexes of the cathode and the protective layer, and the refractive index of the light block layer may be greater than the refractive indexes of the protective layer and the first encapsulation layer, so as to facilitate light extraction and improvement of light extraction efficiency.

In an exemplary embodiment, the refractive index of the light extraction layer may be about 1.7 to 2.0, the refractive index of the protective layer may be 1.4 to 1.6, and the refractive index of the light block layer may be about 1.8 to 2.1. For example, the refractive index of the light extraction layer may be about 1.8, the refractive index of the protective layer may be 1.5, and the refractive index of the light block layer may be about 1.9.

In an exemplary embodiment, the process of preparing the display substrate in this embodiment is basically similar to that in the above embodiment, except that forming the modulation structure layer on the light emitting structure layer may include: sequentially evaporating a light extraction layer 31, a protective layer 32 and a light block layer 33 by using an open mask, and forming a connected layer of the light extraction layer 31, the protective layer 32 and the light block layer 33 on the display substrate, that is, the light extraction layers 31, the protective layers 32 and the light block layers 33 of all sub-pixels are connected.

In this exemplary embodiment of the present disclosure, the modulation structure layer is disposed between the light emitting structure layer and the encapsulation structure layer, the modulation structure layer includes the light extraction layer, the protective layer and the light block layer, and the refractive index of the protective layer is less than the refractive indexes of the light extraction layer and the light block layer, thus not only effectively improving the service life of the OLED display device in the ultraviolet irradiation environment, but also effectively improving the light extraction efficiency and the emergent light intensity of the OLED display device.

FIG. 13 is a schematic diagram of a sectional structure of another display substrate according to an exemplary embodiment of the present disclosure, illustrating a structure of a sub-pixel of an OLED display substrate. Referring to FIG. 13, in a plane perpendicular to the display substrate, the display substrate may include a driving circuit layer 103 disposed on a base substrate 10, a light emitting structure layer 104 disposed on the side of the driving circuit layer 103 away from the base substrate 10, a modulation structure layer 105 disposed on the side of the light emitting structure layer 104 away from the base substrate 10, and an encapsulation structure layer 106 disposed on the side of the modulation structure layer 105 away from the base substrate 10. In an exemplary embodiment, the structures of the driving circuit layer 103, the light emitting structure layer 104 and the encapsulation structure layer 106 may be similar to those in the above embodiment. In an exemplary embodiment, the modulation structure layer 105 may include a light block layer 33, and the light block layer 33 is configured to block ultraviolet rays from being incident on the pixel definition layer 22. The light block layer 33 is disposed on the side of a cathode 24 away from the base substrate 10, and the refractive index of the light block layer 33 may be greater than the refractive indexes of the cathode 24 and the first encapsulation layer. In an exemplary embodiment, a light outlet is disposed in the light block layer 33, and the light outlet exposes the pixel opening in the pixel definition layer, so as to effectively block ultraviolet rays from being incident on the pixel definition layer without affecting the light extraction of the light emitting device.

In an exemplary embodiment, an orthographic projection of the light outlet on the base substrate contains an orthographic projection of the pixel opening on the base substrate.

In an exemplary embodiment, the light block layer 33 may be an ultraviolet absorption layer or an ultraviolet reflection layer.

In an exemplary embodiment, the structure of the ultraviolet absorption layer is similar to the structure in the above embodiment.

In an exemplary embodiment, the ultraviolet reflection layer may be a stack structure capable of reflecting ultraviolet rays. For example, the ultraviolet reflection layer may include a plurality of sub-layers which are stacked sequentially. The plurality of sub-layers include a first sub-layer with a first refractive index and a second sub-layer with a second refractive index. The first sub-layer and the second sub-layer are arranged alternately in the plurality of sub-layers to form an ultraviolet block layer.

In an exemplary embodiment, the ultraviolet reflection layer may include three sub-layers, five sub-layers, seven sub-layers, nine sub-layers, eleven layers, etc., the number of sub-layers is odd, and the first layer and the last layer of the plurality of sub-layers are first sub-layers. The materials of the plurality of stacked sub-layers may be the same or different; the thickness of the plurality of stacked sub-layers may be the same or different. The plurality of stacked sub-layers may be formed sequentially through evaporation or Plasma Enhanced Chemical Vapor Deposition (PECVD), which is not limited in the present disclosure.

In an exemplary embodiment, the thickness of the ultraviolet reflection layer may be about 50 nm to 100 nm.

In an exemplary embodiment, the process of preparing the display substrate in this embodiment is basically similar to that in the above embodiment, except that a modulation structure layer is formed on the light emitting structure layer. In an exemplary embodiment, forming the modulation structure layer on the light emitting structure layer may include: respectively evaporating light block layers 33 on different sub-pixels using a fine metal mask. In each sub-pixel, a light outlet 34 is disposed in the light block layer 33, and the light outlet 34 exposes the surface of the cathode 24, referring to FIG. 14.

In an exemplary embodiment, in a plane parallel to the base substrate, the shape of the light outlet may be a square shape, rectangular shape, circular shape, elliptical shape or hexagonal shape, and may be set according to the actual needs, which is not limited in the present disclosure.

In this exemplary embodiment of the present disclosure, the modulation structure layer is disposed between the light emitting structure layer and the encapsulation structure layer, the modulation structure layer includes the light block layer that reduces the incidence of ultraviolet rays into the pixel definition layer, the position of the light block layer corresponds to the position of the pixel definition layer, and the light block layer can effectively absorb most ultraviolet rays in the ultraviolet irradiation environment, thus effectively reducing the intensity of ultraviolet rays entering the pixel definition layer, avoiding or reducing the outgassing of the pixel definition layer, avoiding or slowing down the failure of the organic light emitting layer, effectively improving the service life of the OLED display device in the ultraviolet irradiation environment, avoiding the influence of the light block layer on the emergent light through the light outlet, and effectively improving the light extraction efficiency of the OLED display device.

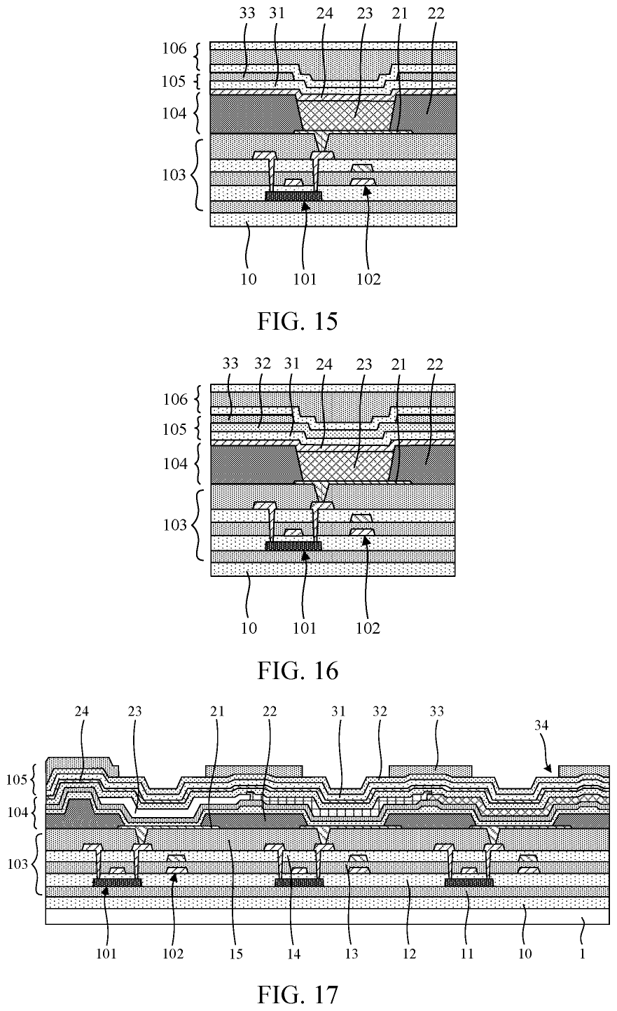

FIG. 15 is a schematic diagram of a sectional structure of another display substrate according to an exemplary embodiment of the present disclosure, illustrating a structure of a sub-pixel of an OLED display substrate. Referring to FIG. 15, in a plane perpendicular to the display substrate, the display substrate may include a driving circuit layer 103 disposed on a base substrate 10, a light emitting structure layer 104 disposed on the side of the driving circuit layer 103 away from the base substrate 10, a modulation structure layer 105 disposed on the side of the light emitting structure layer 104 away from the base substrate 10, and an encapsulation structure layer 106 disposed on the side of the modulation structure layer 105 away from the base substrate 10. In an exemplary embodiment, the structures of the driving circuit layer 103, the light emitting structure layer 104 and the encapsulation structure layer 106 are similar to that in the above embodiment. In an exemplary embodiment, the modulation structure layer 105 includes a light extraction layer 31 and a light block layer 33 which are stacked. The light extraction layer 31 is disposed on the side of a cathode 24 in the light emitting structure layer 104 away from the base substrate 10 and configured to extract light. The light block layer 33 is disposed on the side of the light extraction layer 31 away from the base substrate 10 and configured to block ultraviolet rays from being incident on the pixel definition layer 22. A light outlet is disposed in the light block layer 33, and the light outlet exposes the pixel opening in the pixel definition layer, so as to effectively block ultraviolet rays from being incident on the pixel definition layer without affecting the light extraction of the light emitting device.

In an exemplary embodiment, an orthographic projection of the light outlet on the base substrate contains an orthographic projection of the pixel opening on the base substrate.

In an exemplary embodiment, the light extraction layers 31 may be connected layers, and the light extraction layers 31 of all sub-pixels are connected, that is, the light extraction layers 31 are of an entire surface structure.

In an exemplary embodiment, the structure of the light extraction layer 31 is similar to that in the above embodiment.

In an exemplary embodiment, the light block layer 33 may be an ultraviolet absorption layer or an ultraviolet reflection layer, and the structures of the ultraviolet absorption layer and the ultraviolet reflection layer are similar to those in the above embodiment.

In an exemplary embodiment, the process of preparing the display substrate in the exemplary embodiment of the present disclosure is basically similar to that in the above embodiment, except that a modulation structure layer is formed on the light emitting structure layer. In an exemplary embodiment, forming a modulation structure layer on a light emitting structure layer may include: firstly evaporating light extraction layers 31 sequentially by using an open mask, and forming a connected layer of the light extraction layers 31 on the display substrate, that is, the light extraction layers 31 of all sub-pixels are connected. Then, light block layers 33 are respectively evaporated on different sub-pixels by using a fine metal mask. In each sub-pixel, a light outlet is provided in the light block layer 33, and the light outlet 34 exposes the surface of the protective layer 32.

In this exemplary embodiment of the present disclosure, the modulation structure layer is disposed between the light emitting structure layer and the encapsulation structure layer, the modulation structure layer includes the light extraction layer and the light block layer, the light outlet is disposed in the light block layer, and the orthographic projection of the light outlet in the light block layer on the base substrate contains the orthographic projection of the pixel opening in the pixel definition layer on the base substrate, thus not only effectively improving the service life of the OLED display device in the ultraviolet irradiation environment, but also effectively improving the light extraction efficiency of the OLED display device. The light block layer in the modulation structure layer can effectively absorb most ultraviolet rays in the ultraviolet irradiation environment, effectively reduce the intensity of ultraviolet rays entering the pixel definition layer, avoid or reduce outgassing of the pixel definition layer, avoid or slow down the failure of the organic light emitting layer, and effectively improve the service life of the OLED display device in the ultraviolet irradiation environment. The light outlet can avoid the influence of the light block layer on the emergent light, and effectively improve the light extraction efficiency of the OLED display device. The light extraction layer in the modulation structure layer can not only effectively eliminate the SPP effect and improve the light extraction efficiency, but also effectively adjust the reflectivity and transmittance of the emergent light, effectively adjust the length of the optical micro resonant cavity and improve the emergent light intensity.

FIG. 16 is a schematic diagram of a sectional structure of another display substrate according to an exemplary embodiment of the present disclosure, illustrating a structure of a sub-pixel of an OLED display substrate. Referring to FIG. 16, in a plane perpendicular to the display substrate, the display substrate may include a driving circuit layer 103 disposed on a base substrate 10, a light emitting structure layer 104 disposed on the side of the driving circuit layer 103 away from the base substrate 10, a modulation structure layer 105 disposed on the side of the light emitting structure layer 104 away from the base substrate 10, and an encapsulation structure layer 106 disposed on the side of the modulation structure layer 105 away from the base substrate 10. In an exemplary embodiment, the structures of the driving circuit layer 103, the light emitting structure layer 104 and the encapsulation structure layer 106 are similar to those in the above embodiment. In an exemplary embodiment, the modulation structure layer 105 includes a light extraction layer 31, a protective layer 32 and a light block layer 33 which are stacked. The light extraction layer 31 is disposed on the side of a cathode 24 in the light emitting structure layer 104 away from the base substrate 10 and configured to extract light. The protective layer 32 is disposed on the side of the light extraction layer 31 away from the base substrate 10 and configured to protect the light extraction layer 31. The light block layer 33 is disposed on the side of the protective layer 32 away from the base substrate 10 and configured to block ultraviolet rays from being incident on the pixel definition layer 22. A light outlet is provided in the light block layer 33, and the light outlet exposes the pixel opening on the pixel definition layer, so as to effectively block ultraviolet rays from being incident on the pixel definition layer without affecting the light extraction of the light emitting device.

In an exemplary embodiment, an orthographic projection of the light outlet on the base substrate contains an orthographic projection of the pixel opening on the base substrate.

In an exemplary embodiment, both the light extraction layer 31 and the protective layer 32 may be connected layers, and the light extraction layers 31 and the protective layers 32 of all sub-pixels are connected, that is, the light extraction layers 31 and the protective layers 32 are of an entire surface structure.

In an exemplary embodiment, the structures of the light extraction layer 31 and the protective layer 32 are similar to those in the above embodiment.

In an exemplary embodiment, the light block layer 33 may be an ultraviolet absorption layer or an ultraviolet reflection layer, and the structures of the ultraviolet absorption layer and the ultraviolet reflection layer are similar to those in the above embodiment.

In an exemplary embodiment, the process of preparing the display substrate in the exemplary embodiment of the present disclosure is basically similar to that in the above embodiment, except that a modulation structure layer is formed on the light emitting structure layer. In an exemplary embodiment, forming a modulation structure layer on a light emitting structure layer may include: firstly evaporating a light extraction layer 31 and a protective layer 32 sequentially by using an open mask, forming a connected layer of the light extraction layer 31 and the protective layer 32 on the display substrate, that is, the light extraction layers 31 and the protective layers 32 of all sub-pixels are connected. Then, light block layers 33 are respectively evaporated on different sub-pixels by using a fine metal mask. In each sub-pixel, a light outlet 34 is provided in the light block layer 33, and the light outlet 34 exposes the surface of the protective layer 32, referring to FIG. 17.

In this exemplary embodiment of the present disclosure, the modulation structure layer is disposed between the light emitting structure layer and the encapsulation structure layer, the modulation structure layer includes the light extraction layer, the protective layer and the light block layer, the light outlet is disposed in the light block layer, and the orthographic projection of the light outlet in the light block layer on the base substrate contains the orthographic projection of the pixel opening in the pixel definition layer on the base substrate, thus not only effectively improving the service life of the OLED display device in the ultraviolet irradiation environment, but also effectively improving the light extraction efficiency of the OLED display device. The light block layer in the modulation structure layer can effectively absorb most ultraviolet rays in the ultraviolet irradiation environment, effectively reduce the intensity of ultraviolet rays entering the pixel definition layer, avoid or reduce outgassing of the pixel definition layer, avoid or slow down the failure of the organic light emitting layer, and effectively improve the service life of the OLED display device in the ultraviolet irradiation environment. The light outlet can avoid the influence of the light block layer on the emergent light, and effectively improve the light extraction efficiency of the OLED display device. The light extraction layer in the modulation structure layer can not only effectively eliminate the SPP effect and improve the light extraction efficiency, but also effectively adjust the reflectivity and transmittance of the emergent light, effectively adjust the length of the optical micro resonant cavity and improve the emergent light intensity.

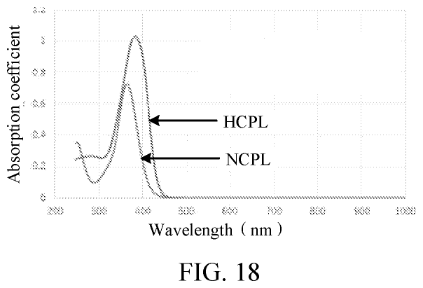

In an exemplary embodiment, corresponding technical solutions can be obtained by correspondingly expanding the above embodiments. For example, in the solution in which the modulation structure layer illustrated in FIG. 12 or FIG. 16 includes a light extraction layer, a protective layer and a light block layer, the material of the light extraction layer may be an aromatic amine organic compound added with an N or O heteroatom, so as to maximize the efficiency of absorbing ultraviolet rays. In some possible embodiments, the light extraction layer may be made of a material with conventional ultraviolet absorption characteristics (NCPL), and the light barrier layer may be made of a material with high ultraviolet absorption characteristics (HCPL). FIG. 18 illustrates absorption curves of NCPL and HCPL at different bands. It can be seen from FIG. 18 that the absorption coefficient of HCPL for light with wavelength of 420 nm is about 7 times that of NCPL, that is, the absorption capacity of HCPL for ultraviolet light is 7 times that of NCPL. As another example, in the scheme in which the modulation structure layer illustrated in FIG. 16 includes a light extraction layer, a protective layer and a light block layer, the material of the light extraction layer may be an aromatic amine organic compound added with an N or O heteroatom, and the light block layer may be a reflecting layer structure to block ultraviolet rays from entering the pixel definition layer to the greatest extent by reflecting and absorbing ultraviolet rays.

The present disclosure further provides a method for preparing a display substrate. In an exemplary embodiment, the method for preparing a display substrate may include:

S1: sequentially forming a driving structure layer and a light emitting structure layer on a base substrate;

S2: forming a modulation structure layer on the light emitting structure layer, wherein the modulation structure layer includes a light extraction layer and a light block layer, the light extraction layer is disposed on the side of a cathode in the light emitting structure layer away from the base substrate, the light block layer is disposed on the side of the light extraction layer away from the base substrate, the refractive index of the light extraction layer is greater than the refractive indexes of the cathode and the light block layer, and the light block layer is configured to block ultraviolet rays from being incident on a pixel definition layer.

In an exemplary embodiment, the method for preparing a display substrate may further include:

S3: forming an encapsulation structure layer on the modulation structure layer.

In an exemplary embodiment, the encapsulation structure layer includes a first encapsulation layer disposed on the side of the modulation structure layer away from the base substrate, a second encapsulation layer disposed on the side of the first encapsulation layer away from the base substrate, and a third encapsulation layer disposed on the side of the second encapsulation layer away from the base substrate; the refractive index of the light block layer is less than the refractive index of the first encapsulation layer.

In an exemplary embodiment, the modulation structure layer further includes a protective layer, the protective layer is disposed between the light extraction layer and the light block layer, the refractive index of the light extraction layer is greater than the refractive indexes of the cathode and the protective layer, and the refractive index of the light block layer is greater than the refractive indexes of the protective layer and the first encapsulation layer in the encapsulation structure layer.

In an exemplary embodiment, the light emitting structure layer includes an anode and a pixel definition layer; a pixel opening exposing the anode is disposed in the pixel definition layer, a light outlet is disposed in the light block layer, and an orthographic projection of the light outlet on the base substrate contains an orthographic projection of the pixel opening on the base substrate.

The present disclosure further provides a display device, which includes the display substrate. The display device may be any product or component with a display function, such as mobile phone, tablet computer, TV, display, notebook computer, digital photo frame, navigator, vehicle-mounted display, smart watch or smart bracelet.

Although the embodiments disclosed in the present disclosure are as above, the content described is only for the convenience of understanding the present disclosure and is not used to limit the present disclosure. Those skilled in the art may make any modification and change in the form and details of the implementation without departing from the spirit and scope of the present disclosure. However, the scope of protection of the present disclosure should still be subject to the scope defined by the attached claims.

What is claimed is:

1. A display substrate, comprising a driving structure layer disposed on a base substrate, a light emitting structure layer disposed on a side of the driving structure layer away from the base substrate, and a modulation structure layer disposed on a side of the light emitting structure layer away from the base substrate,
wherein the modulation structure layer comprises a light extraction layer and a light block layer, the light extraction layer is disposed on a side of a cathode in the light emitting structure layer away from the base substrate, the light block layer is disposed on a side of the light extraction layer away from the base substrate, a refractive index of the light extraction layer is greater than refractive indexes of the cathode and the light block layer, and the light block layer is configured to block ultraviolet rays from being incident on a pixel definition layer.

2. The display substrate according to claim 1, wherein the display substrate further comprises an encapsulation structure layer disposed on a side of the modulation structure layer away from the base substrate, the encapsulation structure layer comprises a first encapsulation layer disposed on a side of the modulation structure layer away from the base substrate, a second encapsulation layer disposed on a side of the first encapsulation layer away from the base substrate, and a third encapsulation layer disposed on a side of the second encapsulation layer away from the base substrate; the refractive index of the light block layer is less than a refractive index of the first encapsulation layer.

3. The display substrate according to claim 42, wherein the modulation structure layer further comprises a protective layer, the protective layer is disposed between the light extraction layer and the light block layer, the refractive index of the light extraction layer is greater than refractive indexes of the cathode and the protective layer, and the refractive index of the light block layer is greater than refractive indexes of the protective layer and the first encapsulation layer in the encapsulation structure layer.

4. The display substrate according to claim 3, wherein a material of the light extraction layer comprises an aromatic amine organic matter and a material of the protective layer comprises lithium fluoride.

5. The display substrate according to claim 3, wherein thickness of the light extraction layer is 60 nm to 100 nm, thickness of the protective layer is 60 nm to 100 nm, and thickness of the light block layer is greater than 50 nm.

6. The display substrate according to claim 3, wherein the refractive index of the light extraction layer is 1.7 to 2.0, the refractive index of the protective layer is 1.4 to 1.6, and the refractive index of the light block layer is 1.6 to 2.1.

7. The display substrate according to claim 1, wherein the light emitting structure layer comprises an anode and the pixel definition layer; a pixel opening exposing the anode is disposed in the pixel definition layer, a light outlet is disposed in the light block layer, and an orthographic projection of the light outlet on the base substrate contains an orthographic projection of the pixel opening on the base substrate.

8. The display substrate according to claim 7, wherein the light block layer comprises any one or more of an ultraviolet absorption layer and an ultraviolet reflection layer.

9. The display substrate according to claim 8, wherein the ultraviolet absorption layer comprises an aromatic amine organic matter added with an N heteroatom or an O heteroatom.

10. The display substrate according to claim 8, wherein the ultraviolet reflection layer comprises a plurality of sub-layers stacked sequentially, the plurality of sub-layers comprise a first sub-layer with a first refractive index and a second sub-layer with a second refractive index, and the first sub-layer and the second sub-layer are arranged alternately in the plurality of sub-layers.

11. A display device, comprising the display substrate according to claim 1.

12. A method for preparing a display substrate, comprising:
sequentially forming a driving structure layer and a light emitting structure layer on a base substrate; and
forming a modulation structure layer on the light emitting structure layer,
wherein the modulation structure layer comprises a light extraction layer and a light block layer, the light extraction layer is disposed on a side of a cathode in the light emitting structure layer away from the base substrate, the light block layer is disposed on a side of the light extraction layer away from the base substrate, a refractive index of the light extraction layer is greater than refractive indexes of the cathode and the light block layer, and the light block layer is configured to block ultraviolet rays from being incident on a pixel definition layer.

13. The method according to claim 12, further comprising:
forming an encapsulation structure layer on the modulation structure layer, wherein the encapsulation structure layer comprises a first encapsulation layer disposed on a side of the modulation structure layer away from the base substrate, a second encapsulation layer disposed on a side of the first encapsulation layer away from the base substrate, and a third encapsulation layer disposed on a side of the second encapsulation layer away from the base substrate; the refractive index of the light block layer is less than a refractive index of the first encapsulation layer.

14. The method according to claim 13, wherein the modulation structure layer further comprises a protective layer, the protective layer is disposed between the light extraction layer and the light block layer, the refractive index of the light extraction layer is greater than refractive indexes of the cathode and the protective layer, and the refractive index of the light block layer is greater than refractive indexes of the protective layer and the first encapsulation layer in the encapsulation structure layer.

15. The method according to claim 12, wherein the light emitting structure layer comprises an anode and the pixel definition layer; a pixel opening exposing the anode is disposed in the pixel definition layer, a light outlet is disposed in the light block layer, and an orthographic projection of the light outlet on the base substrate contains an orthographic projection of the pixel opening on the base substrate.

16. The display substrate according to claim 2, wherein the light emitting structure layer comprises an anode and the pixel definition layer; a pixel opening exposing the anode is disposed in the pixel definition layer, a light outlet is disposed in the light block layer, and an orthographic projection of the light outlet on the base substrate contains an orthographic projection of the pixel opening on the base substrate.

17. The display substrate according to claim 16, wherein the light block layer comprises any one or more of an ultraviolet absorption layer and an ultraviolet reflection layer.

18. The display substrate according to claim 17, wherein the ultraviolet absorption layer comprises an aromatic amine organic matter added with an N heteroatom or an O heteroatom.

19. The display substrate according to claim 17, wherein the ultraviolet reflection layer comprises a plurality of sub-layers stacked sequentially, the plurality of sub-layers comprise a first sub-layer with a first refractive index and a second sub-layer with a second refractive index, and the first sub-layer and the second sub-layer are arranged alternately in the plurality of sub-layers.

20. The display substrate according to claim 3, wherein the light emitting structure layer comprises an anode and the pixel definition layer; a pixel opening exposing the anode is disposed in the pixel definition layer, a light outlet is disposed in the light block layer, and an orthographic projection of the light outlet on the base substrate contains an orthographic projection of the pixel opening on the base substrate.
